(19) United States
(12) Patent Application Publication
(10) Pub. No.: US 2024/0290724 A1
(43) Pub. Date: Aug. 29, 2024

(54) THREE-DIMENSIONALLY INTEGRATED MULTI-IC SYSTEM WITH INTERCONNECT COMPONENTS

(71) Applicant: Fraunhofer-Gesellschaft zur Förderung der angewandten Forschung e.V., München (DE)

(72) Inventor: Christof LANDESBERGER, München (DE)

(21) Appl. No.: 18/584,205

(22) Filed: Feb. 22, 2024

(30) Foreign Application Priority Data
Feb. 27, 2023 (EP) 23158836.9

(51) Int. Cl. H01L 23/538; H01L 25/065

(52) U.S. Cl. CPC H01L 23/5385; H01L 23/5386; H01L 25/0652; H01L 23/5387

(57) ABSTRACT

The concept according to the invention disclosed herein relates to a three-dimensionally integrated multi-IC system having a substrate stack which has several substrates stacked vertically one above the other, each substrate defining a respective substrate plane. Active IC components which are electrically interconnected in the respective substrate plane are arranged on the individual substrates. According to the invention, passive interconnect components are suggested which are arranged between two adjacent substrates, wherein the interconnect component each have vertically extending signal line structures configured to establish an electrical connection between two adjacent substrates each.

### CROSS-REFERENCE TO RELATED APPLICATION

This application claims priority from European Application No. 23158836.9, which was filed Feb. 27, 2023, and is incorporated herein by reference in its entirety.

### TECHNICAL FIELD

The present invention belongs to the technical field of semiconductor technology and relates to a three-dimensionally integrated multi-IC (IC: Integrated Circuit) system. Here, several individual ICs are connected to one another both laterally in one plane and vertically across several planes, wherein the degree of integration can be increased significantly by this. Examples of applications for this are neuromorphic chip architectures, which can be realized using the present invention.

### BACKGROUND OF THE INVENTION

In principle, efforts are made in the field of semiconductor technology to increase the integration density of integrated circuits—ICs—in order to increase performance and computing power. Nowadays, there are various approaches to this.

For example, the computing power of semiconductor processors can be increased significantly by parallelizing data processing in the processor. To date, this has been realized by introducing so-called multi-core processors on a single IC component. Several cores are placed laterally next to one another. However, integrating even more computing cores (cores) on a single IC would entail very large chips with an area of several square centimeters. However, this means a considerable risk of waste for the full functionality of the components as well as further increasing demands on the heat dissipation of the large chip.

Chiplet architectures are a well-known solution for integrating even more processor cores. According to this concept, several smaller ICs are built individually and then electrically contacted as closely and densely as possible. One challenge here is minimizing the space used for the contact points (I/O pads) on the individual ICs. This entails, among other things, a very precise assembly technology for the individual ICs on a base substrate in the range of 1 μm.

Further parallelization of computing operations is made possible by the introduction of vertically stacked processors, which is also referred to as 3D integration. This entails vertical contacts between individual IC planes. In principle, it would be desirable to minimize the path length of electrical connections between processors or between processor and memory elements. This is an important requirement with regard to the clock rates and power requirements of such complex IC systems.

Such an arrangement of several individual ICs can also be referred to as multi-IC system. If many individual processors with a large number of connecting lines can also communicate with one another in a three-dimensional arrangement, this can also be referred to as neuromorphic chip architecture.

One difficulty with 3D integration is that the components used do not always have a uniform height, as they are often supplied from different semiconductor manufacturing companies (chip factories).

To solve this problem, the known technology suggests using flexible film connectors-so-called interposers. These interposers are arranged like a kind of adapter between two chip levels in order to connect two ICs with different pad configurations and to compensate for differences in height.

Such an interposer is described, for example, in US 2011/0 165 735 A1. A first IC is arranged on a substrate. A second IC is arranged vertically above it. An interposer is arranged between the two ICs. The interposer electrically connects the two ICs to each other and also establishes an electrical connection to contacts on the substrate. For contacting the interposer with the substrate, US 2011/0 165 735 A1 explicitly dispenses with vertically extending long, thin contact elements, as these are described as being at risk of breaking. Instead, the flattest possible contact pads are used, which are, however, significantly flatter than the flattest IC on the respective substrate. To compensate for this difference in height, the quadrangular interposer has wings flexible on all four outer sides. These four flexible wings are bent downwards so that the IC is enveloped. The bent end of the wings is then connected to the flat contact pads of the substrate. This compensates for the difference in height between the flat contact pad and the higher IC.

However, this “enveloping” of the IC causes waste heat from the IC to build up under the interposer, which can lead to the IC overheating. In addition, the interposer is deformed when the wings are bent, and the production of an interposer with wings is more complex in total. In addition, the number of layers which can be stacked one above the other is very limited because, due to the limited size of the wings, they do not reach down to the substrate over several stacked layers or levels with a high vertical IC stack. In addition, the flat but wide contact pads use more space (in the lateral direction), which is usually not available.

In principle, differences in height between ICs of different heights on different IC levels can therefore be compensated for by the flexible film connectors or interposers described above. However, using a complete substrate in the form of a film for a complete IC level is not an option, as films always carry the risk of high geometric distortion. This means that films can be distorted due to mechanical stresses during assembly such that conductor paths or contacting sections on the film become distorted so that the I/O pads of the ICs can no longer be placed precisely on the contacting sections provided on the film.

In reality, the distance between two distant contact surfaces for chip mounting on a film will not correspond to the distance between the contact surfaces as originally geometrically defined in CAD design. Such deformations and irregular distortions in a film can easily amount to 20 μm or more over a distance of 1 cm to 5 cm. IC connection pads, on the other hand, can have dimensions of only 10 μm or less so that a distortion of 20 μm means that the 10 μm pads can no longer be positioned accurately on the film. Such a distortion of the film would therefore prevent correct adjustment of the ICs from one level to the next.

### SUMMARY

According to an embodiment, a three-dimensionally integrated multi-IC system may have: a substrate stack having several substrates stacked vertically one above the other, each substrate defining a respective substrate plane, wherein active IC components are arranged on the individual substrates and are electrically interconnected in the respective substrate plane, and passive interconnect components arranged between two adjacent substrates, the interconnect components each having vertically extending signal line structures configured to establish an electrical connection between two adjacent substrates each.

A three-dimensionally integrated multi-IC system is provided, in which a substrate stack is provided, which comprises several individual substrates stacked vertically one above the other, each substrate defining a respective substrate plane. One or more active IC components which are electrically interconnected in the respective substrate plane are arranged on the individual substrates. This means that for each substrate plane (or level), the ICs arranged on the respective substrate are interconnected. It is sufficient if a few, but not necessarily all, ICs are interconnected. This would correspond to a horizontal interconnection in the respective substrate plane. According to the invention, the innovative three-dimensionally integrated multi-IC system presented herein has one or more passive interconnect components, each of which is arranged between two adjacent substrates. The interconnect components each have signal line structures extending vertically, i.e. perpendicular to the respective substrate plane. These vertically extending signal line structures are implemented to establish an electrical connection between two vertically adjacent substrates each (in the substrate stack). This allows the ICs mounted on a first substrate to be connected to the ICs mounted on a vertically adjacent second substrate. This corresponds to vertical interconnection between different substrate planes, which is in line with the idea of 3D integration.

Due to the ever-increasing miniaturization and simultaneous increase in integration density, the contact pads of active IC components must be made smaller and smaller. It is therefore important for the small contact pads of an active IC component to be placed as precisely as possible on the corresponding connection pads on the substrate. This is the only way to ensure a vertical connection across several substrate planes. Thin, flexible film (or foil) substrates which deform or are distorted (or warp) mechanically during assembly are therefore unsuitable as a substrate.

However, the present invention makes it possible to use film substrates since vertical contacting takes place in the separate interconnect components according to the invention. The interconnect components according to the invention are implemented as passive components suitable for mass production. For example, they may have only the vertical signal line structures. This makes them inexpensive and easy to manufacture. Due to their characteristic as a passive component, they also generate significantly less heat than active IC components.

For all the reasons mentioned above, the interconnect components according to the invention can be implemented to be relatively large (in relation to their range of functions) so that there is plenty of space on the top and bottom sides of the interconnect components to accommodate the electrical contact pads. This means that the electrical contact pads can be dimensioned to be significantly larger than is possible with active IC components. This in turn has the advantage that even a large distortion of a film substrate can be compensated for within a wide tolerance range during assembly. This means that even if the film substrate is distorted considerably, the connection pads on the film substrate can still be aligned precisely with the relatively large contact pads of the interconnect components.

### BRIEF DESCRIPTION OF THE DRAWINGS

Some embodiments are illustrated exemplarily in the drawings, and are explained below, in which:

FIG. 1A shows a schematic lateral sectional view of an inventive three-dimensionally integrated multi-IC system according to an embodiment;

FIG. 1B shows a schematic perspective view of an inventive three-dimensionally integrated multi-IC system according to an embodiment;

FIGS. 2A, 2B each show an enlarged section of a lateral sectional view of an inventive three-dimensionally integrated multi-IC system according to an embodiment;

FIGS. 3A-3C each show a schematic top view of a single substrate with active IC components and passive interconnect components mounted thereon according to embodiments; and

FIG. 4 shows a schematic perspective view of a single substrate with active IC components and passive interconnect components mounted thereon according to an embodiment.

### DETAILED DESCRIPTION OF THE INVENTION

In the following, embodiments will be described in more detail with reference to the figures, wherein elements with the same or similar function are provided with the same reference numerals.

The subject of the invention is a three-dimensionally integrated semiconductor system, in particular a three-dimensionally integrated multi-IC system which may contain several individual ICs. A three-dimensionally integrated multi-IC system is characterized, among other things, by the fact that several substrates are stacked one above the other. As substrates are usually flat, each substrate defines a substrate plane. Active IC components are arranged on the substrates, which is why each substrate plane also defines an IC plane or plane. In the context of 3D integration, the IC components are said to be horizontally or laterally interconnected if they are interconnected within one and the same substrate plane. On the other hand, the IC components are said to be vertically interconnected if the individual IC components are interconnected across one or more substrate planes. When the terms “horizontal” and “vertical” are used herein, these terms do not necessarily refer to the orientation of the three-dimensionally integrated multi-IC system in space, but are to be interpreted within the jargon commonly used in this technical field. This means that the term “horizontal” is to be understood synonymously with “in parallel to the substrate plane”, and the term “vertical” is to be understood synonymously with “perpendicular to the substrate plane”.

The individual substrates are stacked vertically one above the other to form a vertical layer stack. Within this layer stack, one or more of these substrates can be in the form of a thin, flexible film substrate which can be bent in a non-destructive manner. Alternatively or additionally, it is conceivable for one or more of the substrates to be in the form of an inflexible, non-destructively bendable or rigid semiconductor substrate (e.g. a silicon substrate). This means that flexible film substrates and rigid semiconductor substrates can be combined within a substrate stack. For the sake of simplicity, flexible film substrates are described below as non-limiting examples of a substrate within the substrate stack. However, the description is equally valid for rigid semiconductor substrates.

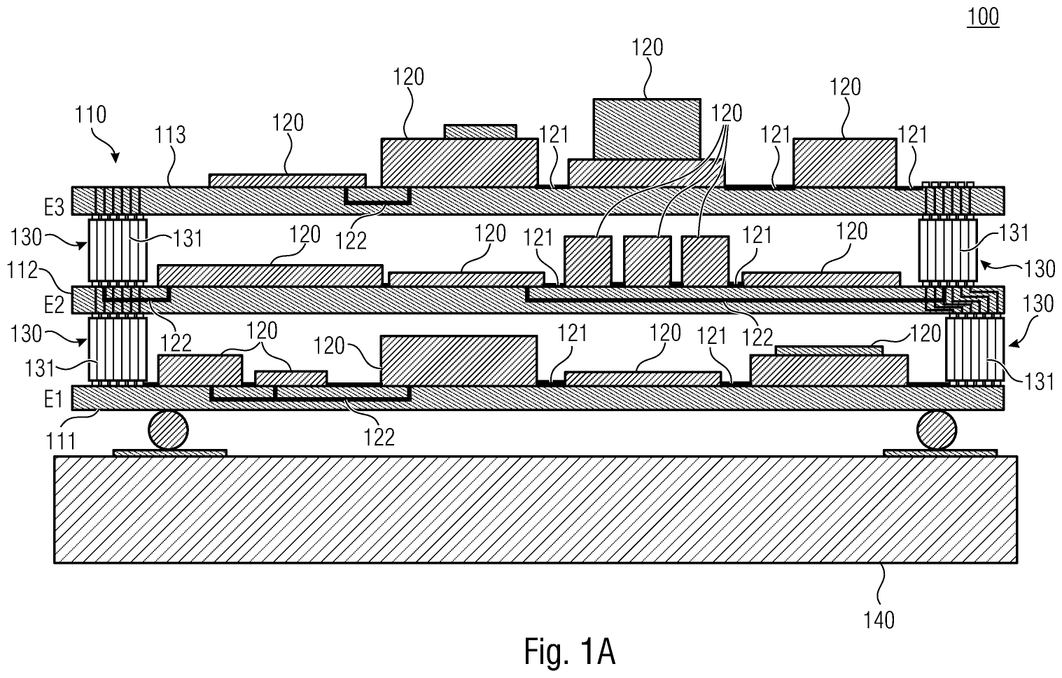

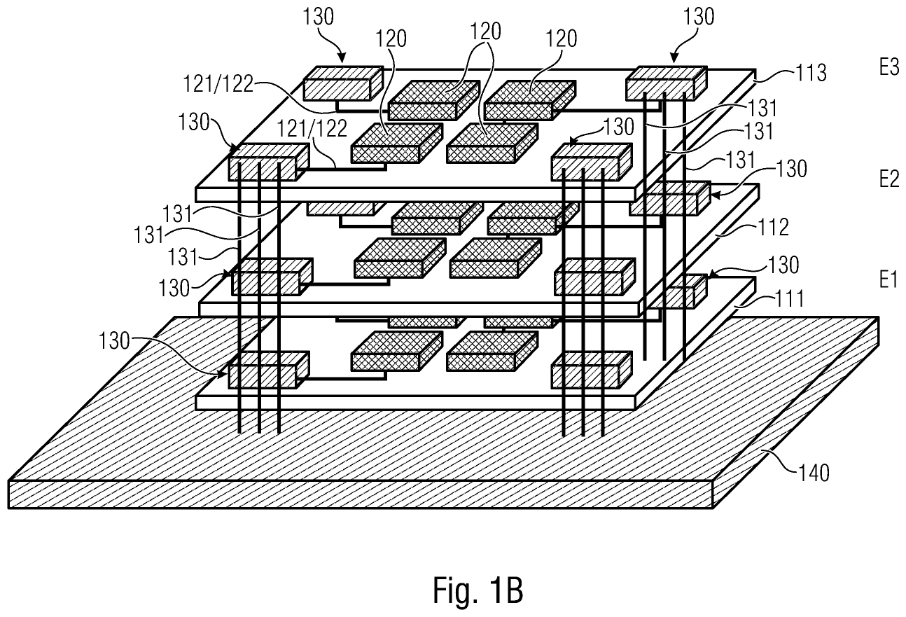

FIGS. 1A and 1B each show embodiments of a three-dimensionally integrated multi-IC system 100 according to the invention. FIG. 1A shows a schematic lateral sectional view of a three-dimensionally integrated multi-IC system 100 and FIG. 1B shows a schematic perspective view of a three-dimensionally integrated multi-IC system 100.

As can be seen in FIGS. 1A and 1B, the three-dimensionally integrated multi-IC system 100 has a substrate stack 110. The substrate stack 110 comprises several substrates 111, 112, 113 stacked vertically one above the other. In this non-limiting embodiment, the substrates 111, 112, 113 are implemented in the form of flexible film substrates. The substrate stack 110 can therefore also be referred to as a film substrate stack. The film substrate stack 110 can be attached to a component carrier substrate 140, which can be in the form of a PCB (printed circuit board), for example, and can also be contacted electrically.

The film substrates 111, 112, 113 are flat and extend in a plane, which is also referred to herein as substrate plane or film plane. Thus, each substrate 111, 112, 113 defines a respective substrate plane E1, E2, E3, which in the context of 3D system integration can also be referred to as horizontal substrate plane or film plane. Accordingly, the first substrate 111 defines a first substrate plane E1, the second substrate 112 defines a second substrate plane E2 adjacent to the first substrate plane E1, and the third substrate 113 defines a third substrate plane E3 adjacent to the second substrate plane E2. The second substrate plane E2 is arranged here between the first substrate plane E1 and the third substrate plane E3.

In the non-limiting embodiments shown in FIGS. 1A and 1B, the substrate stack 110 has three substrates 111, 112, 113 stacked one above the other. However, it is also conceivable for the substrate stack 110 to have only two substrates stacked above each other, or even more than the three shown substrates stacked one above the other.

One or more active IC components 120 (IC: integrated circuit) are arranged on the individual substrates 111, 112, 113. The active IC components 120 may be in the form of unhoused semiconductor components, so-called “bare dies”. The active IC components 120 may be independent self-contained functional units (e.g. microchips). However, the IC components 120 may also be individual smaller circuits of a larger overall circuit. These may be, for example, so-called chiplets, wherein chiplets represent individual small functional blocks of an overall chip. The active IC components 120 may be implemented in the form of three-dimensional integrated circuits, so-called 3D ICs, wherein two or more individual ICs are stacked one above the other and connected vertically (see, for example, FIG. 1A, the two middle 3D ICs in the third film plane E3).

In all cases, the active IC components 120 may be electrically interconnected in order to be able to communicate with one another. They can be interconnected both in a lateral or horizontal direction, i.e. within one and the same substrate or film plane, and in a vertical direction, i.e. across several substrate or film planes.

For the purpose of horizontal wiring within one and the same film plane, the active IC components 120 may be electrically interconnected in the respective film plane E1, E2, E2. This may be realized, for example, by means of thin conductive track structures 121 which are applied to the surfaces of the film substrates 111, 112, 113. This can be done, for example, by printing the respective conductive traces 121, or by means of lithographic structuring. Alternatively or additionally, the active IC components 120 can be electrically coupled to one another by means of integrated wiring 122 within the respective film substrate 111, 112, 113.

For the purpose of vertical wiring across several film planes, the active IC components 120 may be electrically interconnected across at least two adjacent film planes E1, E2, E2. According to the invention, the three-dimensionally integrated multi-IC system 100 has one or more passive interconnect components 130 for this purpose.

The interconnect components 130 are each arranged between two adjacent film substrates 111, 112, 113. The interconnect components 130 each contain one or more vertically extending signal line structures 131. These extend essentially in a straight line through the interior of an interconnect component 130, in particular between a first side (e.g. lower side) of an interconnect component 130 facing a first substrate 111 and an opposite second side (e.g. upper side) of the respective interconnect component 130 facing a second substrate 113.

The vertically extending signal line structures 131 may in principle be present in any number and/or in any arrangement within a respective interconnect component 130. The interconnect components 130 can be implemented such that they have only vertical signal line structures 131.

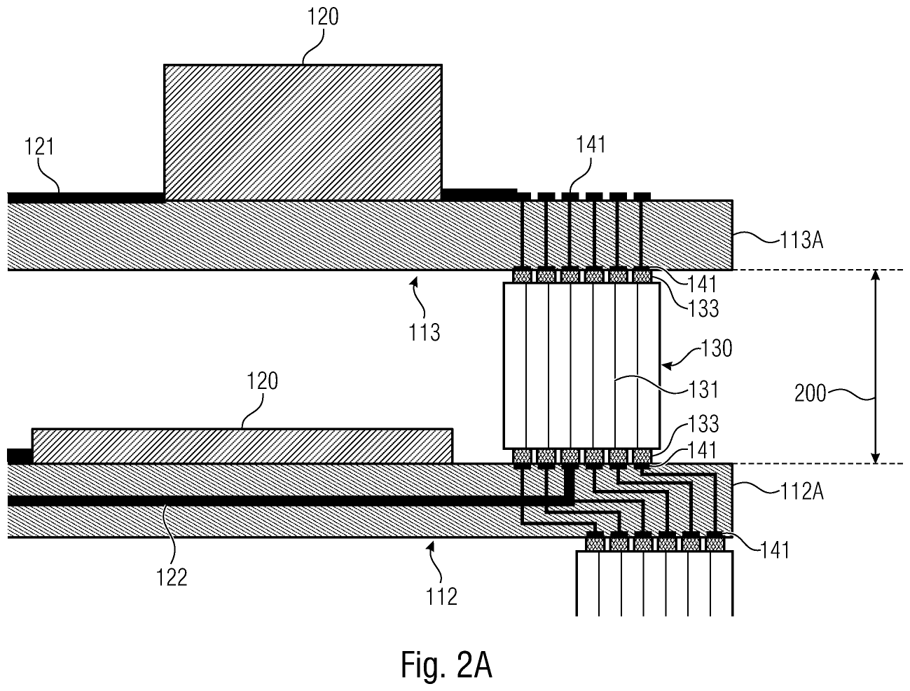

The vertically extending signal line structures 131 are implemented to establish an electrical connection between two adjacent film substrates 111, 112, 113 each, which will be explained in more detail below with reference to FIGS. 2A and 2B.

In this way, for example, the IC components 120 arranged on the second film substrate 112 can be electrically contacted or connected to the IC components 120 on the underlying first film substrate 111 and/or to the IC components 120 on the overlying third film substrate 113. Thus, an electrical connection can be realized across several film planes E1, E2, E3. This is also referred to as vertical contacting. This vertical contacting for connection or communication across several vertical planes is characteristic of 3D system integration.

To enable vertical contacting across multiple film planes E1, E2, E3, at least one active IC component 120 is to be electrically connected to at least one interconnect component 130 in the corresponding film planes E1, E2, E3. More generally, one or more active IC components 120 within a film plane may be electrically connected to one or more passive interconnect components 130 on the same film plane. The IC components 120 may be connected directly to the interconnect components 130, or indirectly, i.e. via one or more interconnected IC components 120.

The interconnect components 130 themselves may be implemented in the form of chips, and in particular in the form of semiconductor chips. This makes manufacturing these interconnect components 130 straightforward, as they can be manufactured in chip factories using sophisticated manufacturing processes.

For example, the interconnect components 130 may have a semiconductor material (e.g. silicon) or consist of a semiconductor material. In this case, the vertically extending signal line structures 131 could, for example, be implemented in the form of conductive through contactings extending through the respective interconnect component 130. In the case of silicon, for example, these may be so-called TSVs (through silicon vias).

Alternatively, the interconnect components 130 could comprise an electrically insulating material or consist of an electrically insulating material, in which case the vertically extending signal line structures 131 could be implemented in the form of channels extending through the respective interconnect component 130, which are filled or coated with an electrically conductive material. This variation could be suitable, for example, if only a small number (e.g. 50 or less) of vertical signal line structures 131 are provided.

The interconnect components 130 may be made from different materials. If a large number of vertical electrical contacts 131 is desired, silicon may be of advantage. In this case, the vertical contacts 131 may be implemented as TSVs (through silicon vias). For a smaller number of vertical contacts 131, e.g. less than 50 per interconnect component 130, materials such as ceramic, glass or the printed circuit board material FR4, as well as other insulating materials may also be used to manufacture the interconnect components 130. The vertical contacts 131 through the interconnect components 130 may then be implemented in the form of metal-filled bores or laser holes with electrically conductive filling or coating.

The contacting between the substrates 111, 112, 113 and the respective interconnect components 130 arranged therebetween can be made via contact pads, which are provided on the upper side (facing one substrate 113) and on the lower side (facing the opposite other substrate 111) of the interconnect component 130.

FIGS. 2A and 2B each show enlarged representations of the connection or contacting between an interconnect component 130 according to the invention and the individual substrates 112, 113. The substrates 112, 113 each have one or more terminal pads 141, to which the active IC components 120 can be connected within the respective substrate plane. The terminal pads 141 can be provided on both sides of the respective substrates 112, 113.

In addition, the passive interconnect components 130 can be contacted with these terminal pads 141 between two substrate planes. For this purpose, the interconnect components 130 each have one or more contact pads 133 on their upper and lower sides facing the substrates 112, 113. The contact pads 133 are configured to be contacted with the terminal pads 141 on the respective substrate 112, 113. The individual contact pads 133 may each be coupled to exactly one vertically extending signal line structure 131, i.e. one contact pad 133 can be provided per signal line structure 131. In this way, a vertical electrical connection of the active IC components 120 can be realized across several substrate planes.

The interconnect components 130 according to the invention are configured as passive elements. For example, they can only have the vertically extending signal line structures 131 as the sole functional feature. In addition, the number of signal line structures 131 in the interconnect component 130 can be kept small. For these reasons, the contact pads 133 on the top and bottom sides of the interconnect components 130 can be significantly larger in size compared to contact pads (e.g. I/O pads) of active IC components 120. This relates in particular to the lateral dimensions of the contact pads 133.

The contact pads 133, which can be dimensioned larger (in the lateral direction), have the advantage that even a large distortion of a film substrate 112, 113 can be compensated for within a wide tolerance range during assembly. This means that even if the film substrate 112, 113 is distorted considerably during assembly, the terminal pads 141 on the film substrate 112, 113 can still be properly contacted with the relatively large contact pads 133 of the interconnect components 130 since the contact pads 133 each have a relatively large surface area with respect to which the terminal pads 141 of the substrate 112, 113 can be aligned precisely. The (laterally) enlarged contact pads 133 can thus compensate for a (lateral) distortion of the film substrate 112, 113 up to a certain extent, thereby enabling the use of films as substrate material in the three-dimensionally integrated multi-IC system 100 according to the invention. The same arguments also apply in the event that the terminal pads 141 of the respective substrate 112, 113 are larger than the contact pads 133 on the respective interconnect component 130.

As can be seen in FIG. 2A, vertical signal line structures 132 may extend through the respective substrate 112, 113. These can be connected to the terminal pads 141 (present on both sides) on the respective substrate 112, 113 The vertical signal line structures 132 extending through the substrate 112, 113 can match in terms of number and/or positioning with one or more vertical signal line structures 131 of an interconnect component 130, i.e. one vertical signal line structure 131 of an interconnect component 130 can be coupled to one of the vertical signal line structures 132 extending through the respective substrate 112, 113 each.

As can also be seen in FIG. 2A, the signal line structures 132 extending vertically through the respective substrate 112, 113 do not necessarily have to be straight, but may also have bends, folds and the like. The same also applies to the vertical signal line structures 131 extending through an interconnect component 130. It is important that they provide a vertical electrical connection between at least two different or adjacent substrate planes E1, E2, E3.

In principle, the active IC components 120 can be contacted on a film substrate 111, 112, 113 using different methods. For example, flip-chip mounting with solder metallization or conductive adhesives such as ACA (anisotropic conductive adhesive) or ACF (anisotropic conductive film) are conceivable. Thermo-compression contacting methods are also suitable. The same applies to the interconnect components 130.

The contact pads 133 of the interconnect components 130 can, for example, be connected to the terminal pads 141 of two adjacent substrates 111, 112, 113 each by means of solder contacting in combination with an underfill adhesive. Here, too, electrically conductive adhesives such as ACA or ACF can be used.

One advantage of using such solder connections and/or conductive adhesives, among other things, is that, in addition to electrical vertical contacting, a mechanical fixation between the individual substrates 111, 112, 113 also takes place at the same time. This means that the mechanical fixation between the substrate planes E1, E2, E3 takes place automatically via the adhesive on the contact pads 133 on the upper and lower sides of the interconnect components 130.

Embodiments of the invention therefore provide for an interconnect component 130 to be attached to the respective terminal pads 141 of two adjacent substrates 112, 113 by means of solder contacting and/or by means of a conductive adhesive, wherein the two adjacent substrates 112, 113 are electrically and mechanically fixed to each other.

As a result, very good mechanical fixation can be achieved, which can also be controlled via the number of interconnect components 130. Bonding the interconnect components 130 to the substrates 111, 112, 113 does not limit heat dissipation since the interconnect components 130 are not active, i.e. power-consuming and heat-generating components.

The interconnect components 130 can also be used to dissipate heat between the individual substrate planes E1, E2, E3. This results from the fact that the signal line structures 131 extending vertically in the interconnect components 130 may comprise metals, wherein metals generally dissipate heat well.

However, the interconnect components 130 according to the invention are not only used for vertical contacting. They can also be used as essentially uniform spacers between two adjacent substrates 111, 112, 113.

According to the invention, the interconnect components 130 are dimensioned such that a substrate 112 does not come into contact with IC components 120 of an underlying adjacent substrate 111. In other words, the interconnect components 130 ensure that a substrate 112 in a first substrate plane E2 is spaced apart from the IC components 120 of an adjacent substrate 111 in a second substrate plane E1. According to the invention, this is ensured by the fact that the interconnect components 130 arranged on a substrate 111, 112, 113 are each higher than the respective highest active IC component 120 on the same substrate 111, 112, 113. The component height is measured here in the vertical direction, i.e. perpendicular to the respective substrate plane E1, E2, E3.

In the embodiments discussed thus far, film substrates have been described as examples of the usable substrates 111, 112, 113 within a substrate stack 110. In some embodiments, it is conceivable for one or more of the substrates 111, 112, 113 within the substrate stack 110 to be implemented in the form of inflexible or rigid semiconductor substrates, for example in the form of interposers. The semiconductor substrates may, for example, comprise silicon or consist of silicon.

Rigid semiconductor substrates are more stable or stiffer than film substrates, which is why there is significantly less distortion during assembly. In contrast to flexible film substrates, however, rigid semiconductor substrates are much less able to compensate for differences in height between individual IC components 120. Particularly when using semiconductor substrates, it is therefore advisable for the interconnect components 130 of a substrate plane E1, E2, E3 to have essentially the same height. For example, the individual interconnect components 130 may differ in height by less than 30 μm, or by less than 10 μm, or even by less than 5 μm. In the case of rigid semiconductor substrates, it is conceivable for the individual interconnect components 130 to differ in height by less than 2 μm, or even by less than 1 μm.

Since the interconnect components 130 can be manufactured as universal components, it is also conceivable for all the interconnect components 130 used within an entire multi-IC system 100 to have essentially the same height, regardless of between which substrates 111, 112, 113 or substrate planes E1, E2, E3 the interconnect components 130 are arranged.

In principle, the interconnect components 130 can be arranged wherever there is space. This means that they can be positioned at any free locations on the respective substrate 111, 112, 113. As can be seen in FIG. 1A, the interconnect components 130 may, for example, be arranged along lateral outer edges of the respective substrate 111, 112, 113. In this case, the outer contour of the interconnect component 130 may be flush with the outer edge of the respective substrate 111, 112, 113. This is shown exemplarily with the interconnect component 130 shown at the bottom right in FIG. 1A. However, it is also conceivable for the interconnect components 130 to be offset laterally inwards, towards the center of the respective substrate 111, 112, 113. This in turn is shown exemplarily using the other interconnect components 130 in FIG. 1A.

Interconnect components 130 which are arranged one above the other, i.e. on different substrate planes E1, E2, E3, can overlap laterally when viewed in the vertical stacking direction, i.e. they can be laterally offset to the left or right of each other. This is illustrated by the two interconnect components 130 on the right in FIG. 1A.

An advantageous embodiment provides for the interconnect components 130 located on different substrate planes E1, E2, E3 to be arranged opposite to one another in the vertical stacking direction, advantageously without a lateral offset. This means that the outer contours of interconnect components 130 located in different substrate planes E1, E2, E3 and arranged one above the other are in common alignment. This is illustrated by the two interconnect components 130 shown on the left in FIG. 1A.

The interconnect components 130 located in different substrate planes E1, E2, E3 are thus advantageously stacked vertically one above the other. Thus, during 3D assembly or stacking of the individual substrates 111, 112, 113, the mechanical pressure is always transferred to the stable interconnect components 130. Thus, pressure-controlled connection techniques are also possible for connecting the individual substrates 111, 112, 113 without subjecting the active IC components 120 on the respective substrates 111, 112, 113 to mechanical stress.

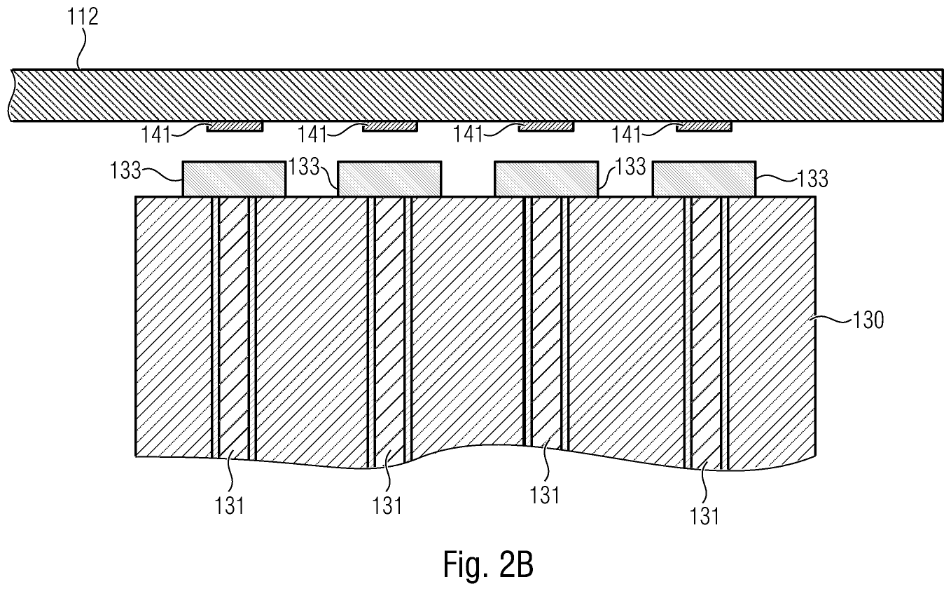

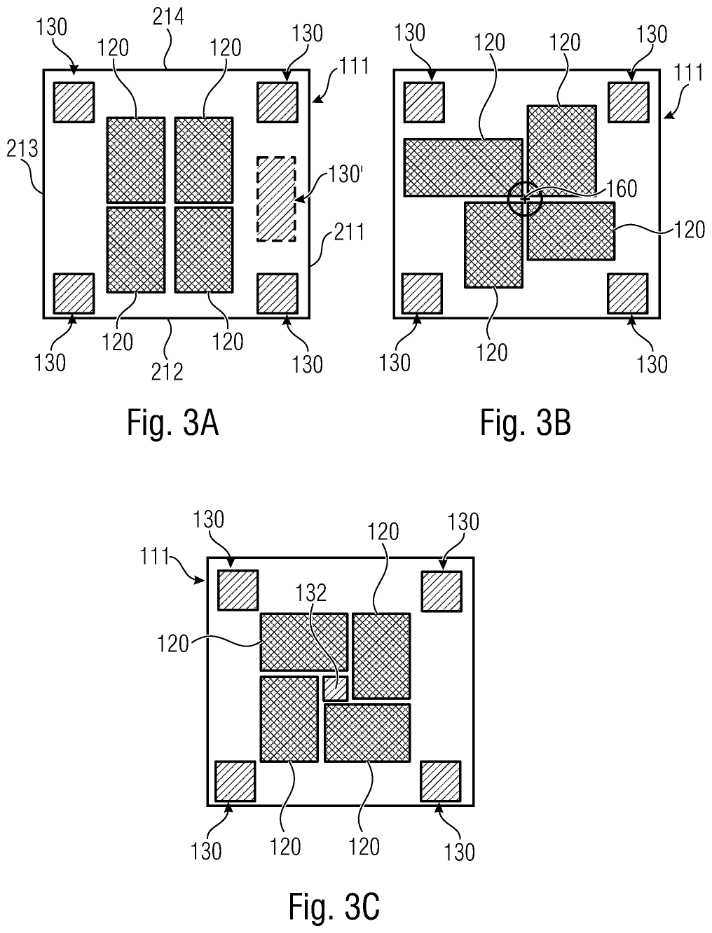

FIGS. 3A, 3B and 3C each show a top view of a single substrate 111 to demonstrate exemplary arrangements of the interconnect components 130 and the active IC components 120. These arrangements also apply to other substrates 112, 113 or other substrate planes.

The interconnect components 130 can initially be of any geometric shape. Preferably, the interconnect components 130 may be quadrangular. The interconnect components 130 can be square or rectangular (see interconnect component 130′ in FIG. 3A).

The substrate 111 itself may also have a quadrangular, e.g. square or rectangular, shape. For example, the interconnect components 130 may be positioned in all four corners of the square substrate 111.

Alternatively or additionally, one or more interconnect components 130 may be positioned along the lateral outer edges 211, 212, 213, 214 (FIG. 3A) of the substrate 111, as is illustrated by the optional interconnect component 130′ shown in dashed lines.

In principle, any number of interconnect components 130 can be arranged at any free positions on the substrate 111. A large number of interconnect components 130 may be of advantage, for example, in order to provide additional support for the substrate 111. If vertical electrical contacting is not necessary, additional passive interconnect components 132 (FIG. 3C) can also be used, which do not have vertically extending signal line structures 131. In order to ensure a uniform distance between two substrate planes, it is of advantage if these additional interconnect components 132 are of the same height as the other interconnect components 130, or differ in height from the other interconnect components 130 by less than 30 μm, or by less than 10 μm, or even by less than 5 μm.

In principle, the arrangement of the active IC components 120 on the substrate 111 can also be selected largely freely. For example, the IC components 120 can be arranged next to one another in the same orientation (FIG. 3A). However, the IC components 120 may also be arranged in a mill wheel-like manner, with one corner of each IC component 120 pointing to a common center 160 (FIG. 3B). However, the IC components 120 may also be arranged in a window-like configuration, wherein the IC components 120 define a rectangular outer contour (FIG. 3C). In the two latter embodiments, two adjacent IC components 120 may always be arranged to be offset by 90° relative to each other.

It may be of advantage to place the interconnect components 130 increasingly in areas in which the active IC components 120 in the individual substrate planes E1, E2, E2 generate increased heat dissipation since the interconnect components 130 can dissipate this heat, in particular if they are implemented in the form of silicon components with many TSV contacts.

Particularly in cases in which the active IC components 120 are chiplets, closely spaced placement is desirable in order to realize short interconnection paths between the chiplets 120. Thus, embodiments of the invention provide for two active IC components 120 arranged laterally adjacent to each other on the same substrate 111 to be arranged at a distance of 10 μm to 300 μm from each other. This can be made possible by applying very fine metal conductive trace structures on a substrate 111, on which the IC components 120 can then be arranged. This allows micrometer-precise placement of the IC components 120 with very close spacing, e.g. only 10 μm to 50 μm from the adjacent IC.

For this purpose, it may be advantageous to use polyimide films as substrate material for the substrates 111, 112, 113 since these can be provided with the fine metal conductive trace structures mentioned above. Polyimide films also have other advantages. For example, they are thermally stable so that soldering processes can be used to contact the IC components 120 and/or the interconnect components 130 on the respective film substrate 111, 112, 113. Films with dielectric properties adapted for high-frequency applications would also be conceivable.

The aspect of heat dissipation is also of great importance in vertical 3D-integrated multi-IC systems 100. The more active IC components 120 are installed per substrate plane E1, E2, E3 and the more substrates 111, 112, 113 are stacked one above the other, the greater the heat generated by the active IC components 120. In order to avoid failures of individual IC components 120 or even failure of the entire 3D-integrated multi-IC system 100, this waste heat must be dissipated efficiently from the substrate stack 110.

Thus, embodiments of the invention provide for two adjacent substrates 112, 113 to be vertically spaced from each other on their respective lateral outer sides 112A, 113A (FIG. 2A) so that air can circulate between these two adjacent substrates 112, 113. This is shown symbolically in FIG. 2A by means of the double arrow 200. This can be made possible in a simple manner by means of the interconnect components 130 according to the invention.

This is of particular advantage for film substrates as the film stack 110 can remain “open” as far as possible. The heat-producing active IC components 120 on the individual film substrates 111, 112, 113 are not completely embedded or encapsulated compared to previously known embedding technologies in printed circuit boards. Thus, the inner areas of the respective film substrates 111, 112, 113 can also be cooled by an air flow (passively or actively). Such an arrangement allows significantly improved heat dissipation. However, of course, the same also applies to rigid semiconductor substrates.

A further improvement in heat dissipation can be achieved by providing unused areas on the substrates 111, 112, 113 with a metal layer, e.g. copper. This results in a larger cooling surface and helps to spread the heat. These copper cooling surfaces should be electrically isolated from the electrical connections between the IC components 120 and/or the interconnect components 130.

As already mentioned at the beginning, the electrical connection lines between the IC components 120 and/or the interconnect components 130 can be implemented in the form of conductive trace structures 121 applied to the respective substrate 111, 112, 113 and/or in the form of wiring 122 integrated into the substrate 111, 112, 113.

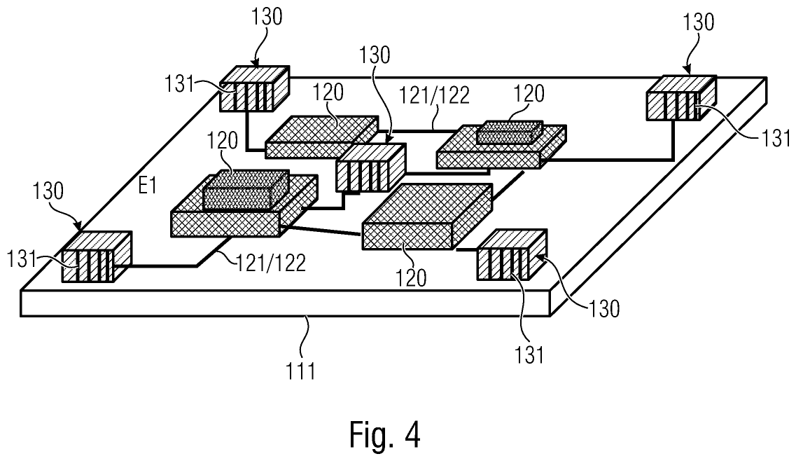

Finally, FIG. 4 again shows a schematic perspective view of a single substrate 111 or a single substrate plane E1 with an exemplary lateral or horizontal connection layout between several IC components 120 and interconnect components 130. In principle, it is conceivable for, within one and the same substrate plane E1, one or more active IC components 120 to be connected to one or more other active IC components 120. This means that the IC components 120 located on the same substrate plane E1 can be directly or indirectly connected horizontally to one another.

However, it would also be conceivable for individual IC components 120 within a substrate plane E1 not to be connected horizontally to other IC components 120 on this substrate plane E1 but instead to be connected exclusively vertically to IC components 120 on other substrate planes E2, E3. For this purpose, they could be connected horizontally exclusively to one or more interconnect components 130, which establish the vertical connection to the respective adjacent substrate. In general, thus, one or more IC components 120 can be contacted directly or indirectly with one or more interconnect components 130 within a substrate plane E1.

Another important aspect of 3D system integration is achieving the highest possible transmission rate, both in a horizontal and a vertical direction. In order to allow high transmission rates between the IC components 120 connected horizontally to one another on a substrate plane E1, E2, E3, the connecting lines 121, 122 on the respective substrate 111 can be implemented, for example, as high-frequency-compatible conductive traces. These can be so-called “grounded coplanar wave guides” (GCPW), for example. In this case, the signal lines 121, 122 would be located on the upper side of the respective substrate 111, between “ground lines” (not shown here) at a certain distance from each other, and a conductive layer would be applied to the underside of the substrate 111 as a “ground plane”. Electrically conductive vias extending through the substrate 111 could also be provided between the individual “ground sections” on the top and bottom sides of the substrate 111. The vias could be arranged in the form of via chains along the direction of the signal lines.

Such RF lines (“transmission lines”) can be realized particularly well on film substrates. An important advantage here is the smoothness of film surfaces present, especially in the case of polyimide films. This smoothness helps to reduce losses along the conductive traces. Thus, the inventive film architecture also allows realizing high-performance electrical connections 121, 122 between the individual IC components 120 and/or interconnect components 130.

In summary, using the innovative concept presented herein, several different IC components 120 can be electrically interconnected horizontally on a single substrate 111, 112, 113. In the case of integration of chiplet components 120, they can be mounted very close to one another, for example at a distance of only 10 μm to 300 μm. The active IC components 120 may also be placed on a substrate 111, 112, 113 in the form of stacked chips (3D IC) and contacted electrically. The active IC components 120 can be mounted and contacted as unhoused (“bare die”) components.

The vertical electrical connection to an underlying or overlying substrate plane is made via separate chip components, so-called interconnect components 130, which can essentially fulfill two functions. On the one hand, they can serve as essentially uniform spacers between two substrate planes and, on the other hand, they can contain 3D conductive trace structures 131 (e.g. TSVs, “through silicon vias”) extending between the top and bottom sides of the interconnect component 130.

The height of the interconnect components 130 within a substrate plane is largely the same, advantageously with a variation of less than 30 μm. In addition, their height may be greater than the highest IC components 120 present on the same substrate plane.

The integration of many active IC components 120 into a larger chip system 100 involves the risk of a large number of rejects if an electrical test is only possible at the end of integration. With the innovative concept presented here, however, the individual substrate planes can already be tested for electrical functioning before 3D integration. If the individual active IC components 120 were soldered onto a substrate plane, it would even be possible to carry out a repair, and to replace a chip.

The testability of the individual substrate planes as well as the reparability of the IC components 120 on the individual planes offers the advantage of improved productivity for manufacturing such complex 3D chip systems 100.

The 3D system integration concept presented herein has many other advantages. The new chip architecture allows both vertical integration of several IC components 120 and cross-connection between several active IC components 120 in a single substrate plane. The concept is modular, i.e. the IC components 120 used can be easily exchanged in each substrate plane, e.g. to replace them by the next generation of IC components 120. The highly functional active IC components 120 (processor ICs) do not themselves have to have complex TSV structures in the chip in order to allow vertical contacting, which makes manufacturing the same significantly more cost-effective and also more space-saving. According to the invention, the vertical contact elements are instead integrated in the passive interconnect components 130.

The interconnect components 130 for vertical integration are simple and inexpensive mass-produced products which can be used universally and are therefore modular. The “open” architecture of the substrate stack 110 offers good opportunities for heat dissipation from the interior.

The innovative concept presented here can be used, for example, for 3D integration of chip components, for miniaturized chip systems, for the integration of chiplets or for stacking chiplets. This concept for 3D system integration also has great potential for neuromorphic computing architectures.

The present invention allows combining the following advantages in a new modular architecture:
Smaller processor units 120 (e.g. chiplets) can be placed very closely and densely to each other in a substrate plane and communicate with one another
Many connection lines can be realized between IC planes lying one above the other
The resulting open 3D system allows good heat dissipation
The individual IC components 120 in the system 100 can be combined variably, i.e. processor ICs 120 can also be used which do not require special designs for 3D integration, e.g. “through silicon via” (TSV) in the chip, in production. In this way, a modular architecture for different IC components 120 is achieved.

The present invention offers a concept for 3D stacking with cross-linking in all planes and thus provides a basis for a modular chip architecture for neuromorphic computing.

The use of films as substrate material for the individual substrate plane offers the advantage of being able to compensate for small differences in height with the interconnect components 130 and thus to enable largely plane-parallel stacking of the film substrates 111, 112, 113. Nevertheless, the choice of a flexible film as a substrate material for an IC plane contradicts the conventional technical knowledge since a film always entails the risk of geometric distortion.

According to the invention, this problem is solved, among other things, by the fact that the interconnect components 130 can have larger contact pads 133 in order to become tolerant to distortion in the film. This is not obvious at first sight as there is no space on a processor IC for enlarged contact surfaces, or the space used in the relatively expensive silicon wafer processing would be far too expensive. The aim is precisely to reduce the space used by IC components. Therefore, the inventive solution provides for a separate implementation of horizontal and vertical contacting by providing components 130 for the electrical connection between the individual substrate planes, while the IC components 120 are coupled only horizontally to one another with other IC components 120 on the same substrate plane.

The resulting need to manufacture separate components 130 only for the vertical electrical connection between the substrates 111, 112, 113 would initially probably not be considered directly for cost reasons. However, this is made possible by the modular architecture of the concept according to the invention. The interconnect components 130 can, for example, be equipped with a standard array of TSV contacts. This entails only a small amount of space on the chip and the chip can be used for many different stacked systems. In addition, the interconnect chips 130 can be manufactured in large quantities at a uniform and reproducible height. This makes the manufacture of such universally usable interconnect chips 130 actually cost-effective again.

Although some aspects have been described in connection with an apparatus, it is understood that these aspects also constitute a description of the corresponding method so that a block or a component of an apparatus is also to be understood to be a corresponding method step or feature of a method step. Similarly, aspects described in connection with or as a method step also constitute a description of a corresponding block or detail or feature of a corresponding apparatus.

While this invention has been described in terms of several embodiments, there are alterations, permutations, and equivalents which fall within the scope of this invention. It should also be noted that there are many alternative ways of implementing the methods and compositions of the present invention. It is therefore intended that the following appended claims be interpreted as including all such alterations, permutations and equivalents as fall within the true spirit and scope of the present invention.

1. A three-dimensionally integrated multi-IC system comprising:
a substrate stack comprising several substrates stacked vertically one above the other, each substrate defining a respective substrate plane,
wherein active IC components are arranged on the individual substrates and are electrically interconnected in the respective substrate plane, and
passive interconnect components arranged between two adjacent substrates, the interconnect components each comprising vertically extending signal line structures configured to establish an electrical connection between two adjacent substrates each.

2. The three-dimensionally integrated multi-IC system according to claim 1,
wherein one or more of the substrates are implemented in the form of a flexible film substrate.

3. The three-dimensionally integrated multi-IC system according to claim 1,
wherein one or more of the substrates are implemented in the form of a rigid semiconductor substrate.

4. The three-dimensionally integrated multi-IC system according to claim 1,
wherein the interconnect components arranged on one of the substrates are each higher than the highest active IC component on the same substrate.

5. The three-dimensionally integrated multi-IC system according to claim 1,
wherein the individual interconnect components arranged between two adjacent substrates each are of the same height or differ from one another in height by less than 30 μm.

6. The three-dimensionally integrated multi-IC system according to claim 1,
wherein interconnect components located in different substrate planes are arranged opposite each other in the vertical layer stacking direction.

7. The three-dimensionally integrated multi-IC system according to claim 1,
wherein two adjacent substrates each are vertically spaced apart on their respective lateral outer sides by means of the interconnect components so that air can circulate between these two adjacent substrates.

8. The three-dimensionally integrated multi-IC system according to claim 1,
wherein at least one active IC module is electrically connected to at least one passive interconnect component each within a substrate plane.

9. The three-dimensionally integrated multi-IC system according to claim 1,
wherein one or more of the interconnect components comprise a semiconductor material or consist of a semiconductor material, and
wherein the vertically extending signal line structures are implemented in the form of conductive vias extending through the respective interconnect component.

10. The three-dimensionally integrated multi-IC system according to claim 1,
wherein one or more of the interconnect components comprise an electrically insulating material or consist of an electrically insulating material, and
wherein the vertically extending signal line structures are implemented in the form of channels extending through the respective interconnect component, the channels being filled or coated with an electrically conductive material.

11. The three-dimensionally integrated multi-IC system according to claim 1,
wherein the substrates each comprise one or more terminal pads, and wherein the interconnect components each comprise electrical contact pads connected to their respective vertical signal line structures, and
wherein one contact pad of an interconnect component each is electrically contacted with one respective terminal pad of a substrate so that there is an electrically conductive connection between the terminal pads of the respective substrates and the vertically extending signal line structures of the interconnect component arranged between these substrates.

12. The three-dimensionally integrated multi-IC system according to claim 11,
wherein the contact pads of the interconnect components are attached to the respective terminal pads of the two adjacent substrates by means of a solder contact and/or by means of a conductive adhesive, wherein the two adjacent substrates are electrically and mechanically fixed to one another.

13. The three-dimensionally integrated multi-IC system according to claim 1,
wherein at least one additional passive interconnect component is arranged between two adjacent substrates, which comprises no vertically extending signal line structures but which is of the same height as the other interconnect components, or differs in height from the other interconnect components by less than 30 μm.

14. The three-dimensionally integrated multi-IC system according to claim 1,
wherein one or more of the active IC components is/are implemented in the form of unhoused semiconductor components, so-called bare dies, or in the form of chiplets.

15. The three-dimensionally integrated multi-IC system according to claim 1,
wherein two active IC component arranged adjacent to each other on the same substrate are arranged at a distance of 10 μm to 300 μm from each other.
